(19) United States
(12) Patent Application Publication
(10) Pub. No.: US 2023/0367037 A1
(43) Pub. Date: Nov. 16, 2023

(54) METASURFACE OPTICAL ELEMENT PREPARATION METHOD

(71) Applicant: Shphotonics Ltd, Suzhou (CN)

(72) Inventors: Lei SUN, Suzhou (CN); Fei QIN, Suzhou (CN); Xiangping LI, Suzhou (CN)

(21) Appl. No.: 18/316,919

(22) Filed: May 12, 2023

(30) Foreign Application Priority Data
May 16, 2022 (CN) 202210530855.X

(51) Int. Cl. G02B 1/00; B82Y 20/00; G02B 1/14

(52) U.S. Cl. CPC G02B 1/002; B82Y 20/00; G02B 1/14

(57) ABSTRACT

A metasurface optical element preparation method includes coating a nanomaterial over an end surface of a substrate, etching a part of the nanomaterial to the end surface of the substrate to obtain a discrete nano-pillar structure, filling a protection material in a gap of the discrete nano-pillar structure, and etching the protection material to cause a height of the protection material to be uniform and smaller than a height of the discrete nano-pillar structure.

### CROSS-REFERENCE TO RELATED APPLICATION

This application claims priority to Chinese Application No. 202210530855.X, filed on May 16, 2022, the entire content of which is incorporated herein by reference.

### TECHNICAL FIELD

The present disclosure relates to the semiconductor technology field and, in particular, to a metasurface optical element preparation method.

### BACKGROUND

A metasurface optical element is formed by a substrate and discrete nano-pillar structures arranged on a surface of the substrate. Different optical functions, such as optical focusing, imaging, polarization regulation, aberration regulation, and spectrum regulation, are realized through different materials, different structures, and/or different arrangement manners of the discrete nano-pillar structures. Thus, a metasurface device is often applied to a display device and an optical computing apparatus.

The metasurface optical element can collide during use. Since the mechanical stability of the nano-pillars is poor, or the nano-pillars are not bonded to the substrate tightly due to different materials of the nano-pillars and the substrate, the nano-pillars of the surface of the substrate are easily damaged or fall off. Thus, the optical performance and service life of the metasurface device are affected. Thus, a layer of protection material is often coated over the nano-pillars to protect the nano-pillars and enhance the mechanical stability of the nano-pillars.

However, since a difference between a refractive index of the protection material and a refractive index of the nanomaterial is relatively small, a relative refractive index of the metasurface optical element is relatively small, which increases the design difficulty of the metasurface optical element and affects an application effect of the metasurface optical element. Therefore, it is desired to enhance the stability of the nano-pillars of the metasurface optical element while ensuring a relative refractive index between the metasurface optical element and the working environment.

### SUMMARY

Embodiments of the present disclosure provide a metasurface optical element preparation method. The method includes coating a nanomaterial over an end surface of a substrate, etching a part of the nanomaterial to the end surface of the substrate to obtain a discrete nano-pillar structure, filling a protection material in a gap of the discrete nano-pillar structure, and etching the protection material to cause a height of the protection material to be uniform and smaller than a height of the discrete nano-pillar structure.

The present disclosure provides the metasurface optical element preparation method. By coating the nanomaterial on the end surface of the substrate, the nanomaterial can cover the end surface of the substrate. A part of the nanomaterial can be etched to the end surface of the substrate, and the other part of the nanomaterial can be reserved to obtain the discrete nano-pillar structure. The protection material can be filled in the gap of the discrete nanocolumn structure. The protection material in the gaps of the discrete nanocolumn structure can be etched to cause the height of the protection material in each gap to be consistent and smaller than the height of the discrete nano-pillar structure to obtain the metasurface optical element. By filling the protection material in the gaps among the nano-pillars, the nano-pillars can be supported, and the mechanical stability of the nano-pillars can be enhanced. Meanwhile, the height of the protection material is smaller than the height of the nano-pillar, which ensures the relative refractive index between the exposed upper part of the nano-pillar and the working environment.

### BRIEF DESCRIPTION OF THE DRAWINGS

FIG. 1 is a schematic flowchart of a metasurface optical element preparation method according to some embodiments of the present disclosure.

FIG. 2 schematically shows an implementation of a method according to some embodiments of the present disclosure.

FIG. 3 schematically shows an implementation of a method according to some embodiments of the present disclosure.

FIG. 4 schematically shows an implementation of a method according to some embodiments of the present disclosure.

FIG. 5 schematically shows an implementation of a method according to some embodiments of the present disclosure.

FIG. 6 schematically shows an implementation of a method according to some embodiments of the present disclosure.

Reference numerals:

| | | | |
|---|---|---|---|
| 1 Substrate | 2 Nanomaterial | 3 Photoresist | 4 Protection |
| | | | material |
| 5 Glass wafer | 6 Support material | 7 Stop material | |
| 8 Second | | | |
| nanomaterial | | | |

### DETAILED DESCRIPTION OF THE EMBODIMENTS

In the following, some example embodiments are described. As those skilled in the art would recognize, the described embodiments can be modified in various manners, all without departing from the spirit or scope of the present disclosure. Accordingly, the drawings and descriptions are illustrative in nature and not limiting.

In the present disclosure, terms such as “first,” “second,” and “third” can be used to describe various elements, components, regions, layers, and/or parts. However, these elements, components, regions, layers, and/or parts should not be limited by these terms. These terms are only used to distinguish one element, component, region, layer, or part from another element, component, region, layer, or layer. Therefore, a first element, component, region, layer, or part discussed below can also be referred to as a second element, component, region, layer, or part, which does not constitute a departure from the teachings of the present disclosure.

A term specifying a relative spatial relationship, such as “below,” “beneath,” “lower,” “under,” “above,” or “higher,” can be used in the disclosure to describe the relationship of one or more elements or features relative to other one or more elements or features as illustrated in the drawings. These relative spatial terms are intended to also encompass different orientations of the device in use or operation in addition to the orientation shown in the drawings. For example, if the device in a drawing is turned over, an element described as “beneath,” “below,” or “under” another element or feature would then be “above” the other element or feature. Therefore, an example term such as “beneath” or “under” can encompass both above and below. Further, a term such as “before,” “in front of,” “after,” or “subsequently” can similarly be used, for example, to indicate the order in which light passes through the elements. A device can be oriented otherwise (e.g., being rotated by 90 degrees or being at another orientation) while the relative spatial terms used herein still apply. In addition, when a layer is referred to as being “between” two layers, it can be the only layer between the two layers, or there can be one or more intervening layers. In this disclosure, if a light beam encounters a first element and then reaches a second element, the second element is referred to as being downstream the first element or downstream the first element in an optical path, and correspondingly the first element is referred to as being upstream the second element or upstream the second element in the optical path.

Terminology used in the disclosure is for the purpose of describing the embodiments only and is not intended to limit the present disclosure. As used herein, the terms “a,” “an,” and “the” in the singular form are intended to also include the plural form, unless the context clearly indicates otherwise. Terms such as “comprising” and/or “including” specify the presence of stated features, entities, steps, operations, elements, and/or parts, but do not exclude the existence or addition of one or more other features, integers, steps, operations, elements, parts, and/or combinations thereof. As used herein, the term “and/or” includes any and all combinations of one or more of the listed items. The phrases “at least one of A and B” and “at least one of A or B” mean only A, only B, or both A and B.

When an element or layer is referred to as being “on,” “connected to,” “coupled to,” or “adjacent to” another element or layer, the element or layer can be directly on, directly connected to, directly coupled to, or directly adjacent to the other element or layer, or there can be one or more intervening elements or layers. In contrast, when an element or layer is referred to as being “directly on,” “directly connected to,” “directly coupled to,” or “directly adjacent to” another element or layer, then there is no intervening element or layer. “On” or “directly on” should not be interpreted as requiring that one layer completely covers the underlying layer.

In the disclosure, description is made with reference to schematic illustrations of example embodiments (and intermediate structures). As such, changes of the illustrated shapes, for example, as a result of manufacturing techniques and/or tolerances, can be expected. Thus, embodiments of the present disclosure should not be interpreted as being limited to the specific shapes of regions illustrated in the drawings, but are to include deviations in shapes that result, for example, from manufacturing. Therefore, the regions illustrated in the drawings are schematic and their shapes are not intended to illustrate the actual shapes of the regions of the device and are not intended to limit the scope of the present disclosure.

Unless otherwise defined, all terms (including technical and scientific terms) used herein have the same meaning as commonly understood by those of ordinary skill in the art to which this disclosure belongs. Terms such as those defined in commonly used dictionaries should be interpreted to have meanings consistent with their meanings in the relevant field and/or in the context of this disclosure, unless expressly defined otherwise herein.

As used herein, the term “substrate” can refer to the substrate of a diced wafer, or the substrate of an un-diced wafer. Similarly, the terms “chip” and “die” can be used interchangeably, unless such interchange would cause conflict. The term “layer” can include a thin film, and should not be interpreted to indicate a vertical or horizontal thickness, unless otherwise specified.

Embodiments of the present disclosure provide a metasurface optical element preparation method. With the method, mechanical stability of a nano-pillar can be enhanced, and a relative refractive index between the metasurface optical element and a working environment can be ensured.

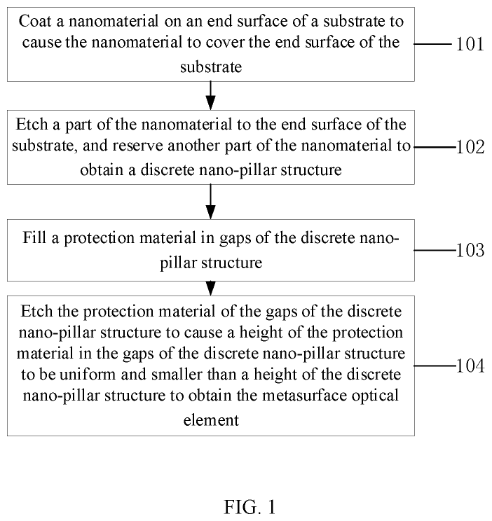

FIG. 1 is a schematic flowchart of a metasurface optical element preparation method 100 (i.e., method 100) according to some embodiments of the present disclosure. The method 100 includes the following processes.

At S101, a nanomaterial 2 is coated on an end surface of a substrate 1 to cause the nanomaterial 2 to cover the end surface of the substrate 1. For example, the nanomaterial 2 covers the entire end surface of the substrate 1.

At S102, parts of the nanomaterial 2 are etched to the end surface of the substrate 1 (i.e., the parts of the nanomaterial 2 are etched to expose corresponding parts of the end surface of the substrate 1), and other parts of the nanomaterial 2 are reserved, to obtain a discrete nano-pillar structure.

At S103, a protection material 4 is filled in gaps of the discrete nano-pillar structure.

At S104, the protection material 4 is etched to cause a height of the protection material 4 to be uniform and smaller than a height of the discrete nano-pillar structure, to obtain the metasurface optical element.

To facilitate understanding, the method 100 is described in detail below in connection with examples.

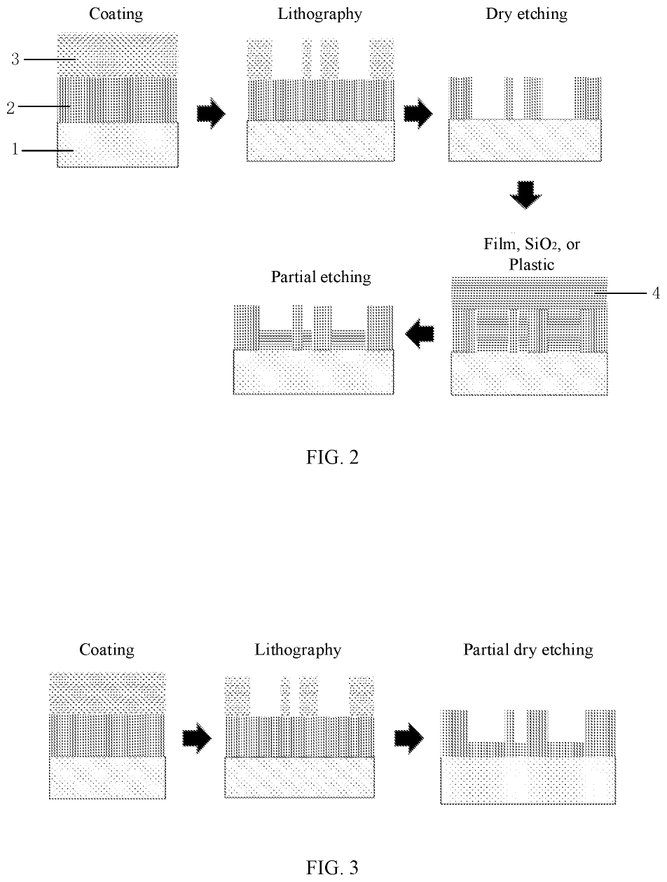

FIG. 2 schematically shows an implementation of the method 100 according to some embodiments of the present disclosure. As shown in FIG. 2, a layer of nanomaterial 2 is coated over the substrate 1 to cause the nanomaterial 2 to cover the end surface of the substrate 1 (such as covering the entire end surface of the substrate 1). A layer of photoresist 3 is coated over the nanomaterial 2. Etching is performed according to predetermined position information of nano-pillars, and the remaining nanomaterial 2 forms the discrete nano-pillar structure constituting the metasurface optical element. Then, the protection material 4 is filled in the gaps of the discrete nano-pillar structure. To cause the protection material 4 to completely fill the gaps among the nano-pillars, the protection material 4 can overflow when being filled. That is, the height of the filled protection material 4 is greater than the height of the discrete nano-pillar structure, to ensure that the protection material 4 completely fills the gaps of the discrete nano-pillar structure. Then, the protection material 4 of the nano-pillar structure is flattened using chemical-mechanical polishing and is selectively etched, such that the protection material 4 has a uniform height smaller than the height of the discrete nano-pillars, to obtain the metasurface optical element.

In embodiments of the present disclosure, by filling the protection material 4 in the gaps of the discrete nano-pillar structure, the nano-pillars can be supported, which effectively prevents the nano-pillars from falling off and enhances the mechanical stability of the nano-pillars. In addition, the height of the protection material 4 can be smaller than the height of the nano-pillars. Although a difference between a refractive index of the nanomaterial 2 and a refractive index of the protection material 4 is relatively small, the difference between the refractive index of the nanomaterial 2 and a refractive index of the air or another working environment is relatively large. The method consistent with the disclosure can allow the nanomaterial 2 and the air be arranged alternately at upper parts of the nano-pillars. Thus, a relative refractive index between the metasurface optical element and the working environment can be ensured.

FIG. 2 only shows only an embodiment of the present disclosure, which does not limit the preparation method of embodiments of the present disclosure. In some other embodiments of the present disclosure, another implementation is provided. For example, the nano-pillar structure can be prepared using a top-down etching process. The etching process can include coating the photoresist 3 or another photosensitive material over the nanomaterial 2, forming a structural pattern using, e.g., electron beam direct write, maskless lithography, mask contact exposure, or mask projection exposure, and then forming the nano-pillar structure using dry etching or wet etching. The nano-pillar structure can also be prepared using a bottom-up growth process. Hole structures that are opposite to the discrete pillar structures can be formed on the photoresist 3 or a hard mask. The nanomaterial 2 can be filled in the hole using the growth process. Then, the photoresist 3 or the hard mask 3 can be removed to obtain the nano-pillar structure.

In some embodiments of the present disclosure, the protection material 4 can include but is not limited to silicon dioxide, plastic, titanium dioxide, silicon, germanium, silicon nitride, and gallium nitride.

In embodiments of the present disclosure, the nanomaterial 2 can include but is not limited to an optical material with a high refraction index and low loss, such as silicon dioxide, crystalline silicon, amorphous silicon, germanium, titanium dioxide, silicon nitride, gallium nitride, and optically transparent organic material.

In embodiments of the present disclosure, the protection material 4 can include, for example, silicon dioxide or plastic. In some embodiments, the protection material 4 can include the same material as the nanomaterial 2, which includes but is not limited to titanium dioxide and silicon. When the protection material 4 is the same as the nanomaterial 2 of the nano-pillar, due to the large bonding force between molecules of a same material, the protection material 4 can have a stronger support effect for the nano-pillars. Thus, the mechanical stability of the nano-pillars can be stronger. Further, using the same material for the protection material 4 can achieve a better temperature stability.

FIG. 3 schematically shows another implementation of the method 100 according to some other embodiments of the present disclosure. In the example shown in FIG. 3, the protection material 4 is the same as the nanomaterial 2. In some embodiments, a film of the nanomaterial 2 is coated over the end surface of the substrate 1. Parts of the nanomaterial 2 are etched to cause the height of the etched parts of the nanomaterial 2 to be smaller than a thickness of the coated nanomaterial 2, to obtain the metasurface optical element. By using the same material for the protection material 4 and the nanomaterial 2, the preparation process can be simplified. Meanwhile, the mechanical stability and the temperature stability of the nano-pillars can be enhanced.

In some other embodiments of the present disclosure, the protection material 4 can be different from the nanomaterial 2.

In some embodiments of the present disclosure, the method further includes, after etching the protection material 4, bonding a glass wafer 5 on a top of the discrete nano-pillar structure to protect the discrete nano-pillar structure.

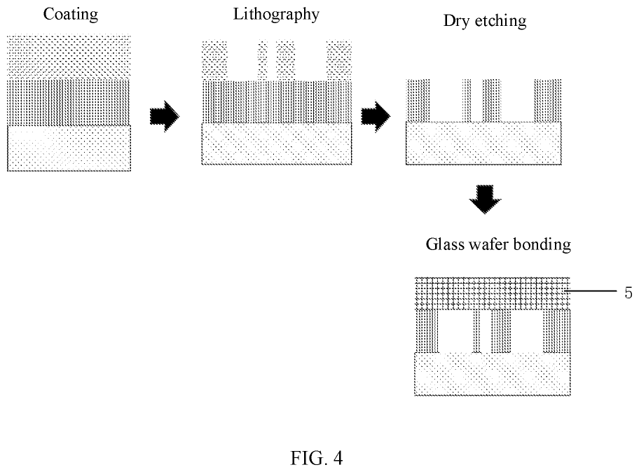

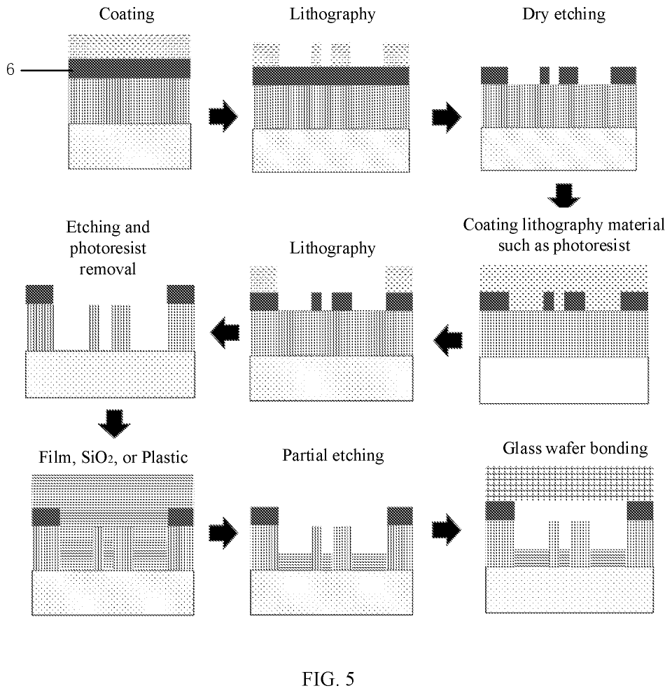

FIG. 4 schematically shows another implementation of the method 100 according to some other embodiments of the present disclosure. In the example shown in FIG. 4, a layer of nanomaterial 2 is coated over the end surface of the substrate 1. Then, the nanomaterial 2 is etched to obtain a discrete nano-pillar structure. The process of filling and etching the protection material 4 in the gaps of the discrete nano-pillar structure is omitted, which is described in detail above and is not repeated here. The glass wafer 5 is bonded to the top of the discrete nano-pillar structure to protect the nano-pillars.

In some embodiments, by bonding the glass wafer 5 at the top of the discrete nano-pillar structure, the nano-pillars can be protected from being damaged, which effectively prevents the nano-pillars from being damaged due to collision during the use of the metasurface optical element. Thus, the service life of the metasurface optical element can be prolonged.

In some embodiments of the present disclosure, the method further includes, after coating the nanomaterial 2 over the end surface of the substrate 1, coating support material 6 on the end surface of the nanomaterial 2 to cause the support material 6 to cover the end surface of the nanomaterial 2 (such as the entire end surface of the nanomaterial 2), and etching parts of the support material 6 to the end surface of the nanomaterial 2 (i.e., etching parts of the support material 6 to expose corresponding parts of the end surface of the nanomaterial 2) and reserving other parts of the support material 6.

In some embodiments of the present disclosure, reserving the other parts of the support material 6 can include using at least one nano-pillar or a larger-scale structure of the discrete nano-pillar structure as a frame of the metasurface optical element and reserving the support material 6 at an end surface of the frame.

In some embodiments of the disclosure, the method further includes bonding the glass wafer 5 to the top of the support material 6 to obtain the metasurface optical element.

FIG. 5 schematically shows another implementation of the method 100 according to some other embodiments of the present disclosure. In the example shown in FIG. 5, the nanomaterial 2 is coated on the end surface of the substrate 1. Then, the support material 6 is coated on the end surface of the nanomaterial 2, parts of the support material 6 are etched, and parts of the nanomaterial 2 are etched. Thus, the discrete nano-pillar structure and the support material 6 over the frame are obtained. In the discrete nano-pillar structure of the metasurface optical element, at least one nano-pillar can be selected as the frame of the metasurface optical element, the frame can be mainly configured for a support function, and the support material 6 over the frame can be kept. Then, the protection material 4 is filled in the gaps of the discrete nano-pillar structure, and the protection material 4 is etched. Then, the glass wafer 5 is bonded at the top of the support material 6 to obtain the metasurface optical element.

In some embodiments, the above embodiments can be combined. The protection material 4 can be filled to support the nano-pillars, such that the nano-pillars do not easily fall off. The height of the protection material 4 can be smaller than the height of the nano-pillars. Thus, the relative refractive index of the metasurface optical element can be increased. In addition, the support material 6 can be provided over the frame. The glass wafer 5 can be bonded over the support material 6. Direct contact between the glass wafer 5 and the nano-pillars can be avoided with the support material 6. Thus, a degree of damage caused by the contact between the glass wafer 5 and the nano-pillars can be reduced, and the glass wafer 5 can be configured to prevent the nano-pillar from being damaged due to an external collision.

In the example shown in FIG. 5, the supporting material 6 can used as a hard mask to assist the formation of the nano-pillars. In some other embodiments, a supporting material 6 on a supporting pillar can also be reserved, and other parts of the support material 6 can be removed by photolithography etching. Then, the processes as shown in FIGS. 2, 3, and 4 can be performed to obtain the nano-pillar. The glass wafer or another transparent material wafer can then be bonded.

In some embodiments of the present disclosure, the method further includes the following processes before coating the nanomaterial 2 on the end surface of the substrate 1.

A stop material 7 can be coated on the end surface of the substrate 1. The stop material 7 can be used to stop etching.

A second nanomaterial can be coated on the end surface of the stop material 7 to obtain the second nanomaterial 8 covering the end surface of the stop material 7 (such as covering the entire end surface of the stop material 7).

Parts of the second nanomaterial 8 can be etched.

A first layer of nanomaterial 2 can be coated on the end surface of the stop material 7 exposed after etching.

In some embodiments of the present disclosure, etching the parts of the second nanomaterial 8 can include the following processes.

The parts of the second nanomaterial 8 can be etched to the stop material 7 (i.e., the parts of the second nanomaterial 8 can be etched to expose corresponding parts of the stop material 7). The other parts of the second nanomaterial 8 can be reserved.

A projection of the gaps of the discrete nano-pillar structure on the end surface of the substrate 1 can be referred to as a first projection.

A projection of the remaining second nanometer material 8 on the end surface of the substrate 1 can be referred to as a second projection.

The second projection can be within the first projection. An area of the second projection can be smaller than an area of the first projection.

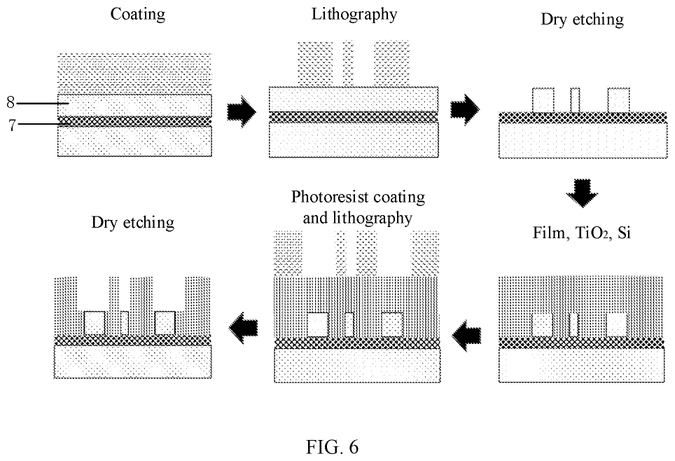

FIG. 6 schematically shows another implementation of the method 100 according to some other embodiments of the present disclosure. In the example shown in FIG. 6, a layer of the stop material 7 is coated on the end surface of the substrate 1. Since the material used as the stop material 7 cannot be etched or is hard to be etched, the etching can automatically stop when the etching is performed to the stop material 7. Then, the second nanomaterial 8 on the end surface of the stop material 7 is coated to obtain a layer of the second nanomaterial 8. Then, according to a predetermined position of the discrete nano-pillar structure, the second nanomaterial 8 is etched to cause a plurality of second nanomaterial pillars to be distributed at the positions of the gaps of the discrete nano-pillar structure. Moreover, a width of each of the plurality of second nanomaterial pillars is smaller than a width of each of the gaps of the discrete nano-pillar structure. Then, the first nanomaterial 2 is coated on the end surface of the exposed stop material 7. A thickness of the first nanomaterial 2 can be larger than a height of the second nanomaterial pillar, and the first nanomaterial 2 can have a planar surface. The photoresist 3 can be coated on the obtained new substrate 1. After processes of structural direct writing, etching, and the subsequent processes are performed, the metasurface optical element can be obtained.

In some embodiments, the nano-pillars can be strengthened by forming the layer of second nanomaterial 8 and the layer of first nanomaterial 2. A contact place between the bottom of a nano-pillar and the substrate 1 can be the layer of first nanomaterial 2. The nano-pillar and the layer of first nanomaterial 2 can have the same material. Compared to the situation that the nano-pillars and the layer of first nanomaterial 2 have different materials, the bonding force can be larger. Thus, the mechanical stability of the nano-pillars can be enhanced.

In summary, in the metasurface optical element preparation method of embodiments of the present disclosure, the protection material 4 can be filled in the gaps of the discrete nano-pillar structure to support the nano-pillars from falling off and enhance the mechanical stability of the nano-pillars. The height of the protection material 4 can be smaller than the height of the nano-pillars, which ensures the relative refractive index between the metasurface optical device and the working environment. The glass wafer 5 can be bonded to protect the nano-pillar from external damages. The support material 6 can be used to support the glass wafer 5 and prevent the glass wafer and the nano-pillars from being abraded. The layer of second nanomaterial 8 and the layer of first nanomaterial 2 can be created to increase the bonding force between the nano-pillar and the substrate 1 to enhance the mechanical stability.

Although embodiments of the present disclosure are described, additional variations and modifications can be made to these embodiments when those skilled in the art learn of the basic inventive concepts. Therefore, the appended claims include embodiments of the present disclosure and all the variations and modifications within the scope of the present disclosure.

In embodiments of the present disclosure, objects, technical solutions, and advantages of the present disclosure are further described in detail. The above embodiments are some embodiments of the present disclosure and are not used to limit the scope of the present disclosure. Any modifications, equivalent replacements, and improvements made based on the technical solution of the present disclosure are within the scope of the present disclosure.

What is claimed is:

1. A metasurface optical element preparation method comprising:
coating a nanomaterial over an end surface of a substrate;
etching a part of the nanomaterial to the end surface of the substrate to obtain a discrete nano-pillar structure;
filling a protection material in a gap of the discrete nano-pillar structure; and
etching the protection material to cause a height of the protection material to be uniform and smaller than a height of the discrete nano-pillar structure.

2. The method according to claim 1, further comprising, after etching the protection material:
bonding a glass wafer to a top of the discrete nano-pillar structure.

3. The method according to claim 1, further comprising, after coating the nano-material on the end surface of the substrate:
coating a support material over an end surface of the nanomaterial; and
etching a part of the support material to the end surface of the nanomaterial.

4. The method according to claim 3, wherein etching the part of the support material includes performing etching on the support material such that another part of the support material over at least one nano-pillar of the discrete nano-pillar structure remains unetched.

5. The method according to claim 4, further comprising:
bonding a glass wafer to a top of the support material.

6. The method according to claim 1,
wherein the nanomaterial is a first nanomaterial;
the method further comprising, before coating the nano-material on the end surface of the substrate:
coating a stop material over the end surface of the substrate;
coating a second nanomaterial on an end surface of the stop material;
etching a part of the second nanomaterial using the stop material as etching stop; and
coating a layer of the first nanomaterial on the end surface of the stop material exposed after etching.

7. The method of claim 6, wherein:
etching the part of the second nanomaterial includes etching the part of the second nanomaterial to the stop material; and
a projection of a remaining part of the second nanomaterial on the end surface of the substrate is within and smaller than a projection of the gap of the discrete nano-pillar structure on the end surface of the substrate.

8. The method according to claim 1, wherein the protection material includes at least one of silicon dioxide, plastic, titanium dioxide, silicon, germanium, silicon nitride, or gallium nitride.

9. The method according to claim 1, wherein the nanomaterial includes at least one of silicon dioxide, crystalline silicon, amorphous silicon, germanium, titanium dioxide, silicon nitride, gallium nitride, or an optically transparent organic material.
